(19) United States
(12) Patent Application Publication
(10) Pub. No.: US 2025/0201709 A1
(43) Pub. Date: Jun. 19, 2025

(54) SEMICONDUCTOR DEVICE AND METHOD OF MANUFACTURING THE SAME

(71) Applicant: Fujian Jinhua Integrated Circuit Co, Ltd., Quanzhou city (CN)

(72) Inventors: Xiaoqin Du, Quanzhou City (CN); Chien-Cheng Tsai, Quanzhou city, Fujian Province (CN); ErPeng Zhuang, Quanzhou city (CN); Chao-Wei Lin, Quanzhou City (CN); Yifei Yan, Quanzhou City (CN); Hui-Huang Chen, Quanzhou city (CN)

(73) Assignee: Fujian JINHUA INTEGRATED CIRCUIT CO, LTD., Quanzhou city (CN)

(21) Appl. No.: 18/586,526

(22) Filed: Feb. 25, 2024

(30) Foreign Application Priority Data
Dec. 14, 2023 (CN) 202311725920.5

(51) Int. Cl. H01L 23/528; H01L 21/263; H01L 21/768; H01L 29/66

(52) U.S. Cl. CPC H01L 23/5283; H01L 21/263; H01L 21/76807; H01L 21/76843; H10D 99/00; H01L 2221/1015

(57) ABSTRACT

A semiconductor device is provided in present invention, including a substrate, a first metal layer on the substrate, a first dielectric layer on the first metal layer, a dual damascene metal structure through the first metal layer and the first dielectric layer and partly in the substrate, an oxide-semiconductor layer between the dual damascene metal structure and the first metal layer, and a metal oxide layer on the oxide-semiconductor layer and between the dual damascene metal structure and the oxide-semiconductor layer, wherein the top surface of oxide-semiconductor layer is lower than the top surface of first dielectric layer, the metal oxide layer includes at least two metal elements and covers the top surface of oxide-semiconductor layer.

### BACKGROUND OF THE INVENTION

### 1. Field of the Invention

The present invention relates generally to a semiconductor device and method of manufacturing the same, and more specifically, to a semiconductor device with oxide-semiconductor layer and method of manufacturing the same.

### 2. Description of the Prior Art

In recent years, oxide-semiconductor (ex. indium gallium zinc oxide, IGZO) has caught the attention of semiconductor industry due to its low cut-off current, high mobility and low manufacturing cost, especially in the application of vertical channel field effect transistor (V-FET), such as vertical channel-all-around field effect transistor (CAA-FET), which may function as a channel layer for the device, cooperating with high-k metal oxide as a gate oxide layer to achieve advantages like excellent low power consumption and low operating voltage, suitable for the field of Internet of things (IoT) devices and any other mobile devices

In the manufacturing process of the device above, oxide-semiconductor is vulnerable to the damage and contamination caused by destructive etching or cleaning process, which may seriously impact the electrical property and performance of the device. Accordingly, those of skilled in the art need to improve current relevant structures and processes, in hope of solving the aforementioned problem.

### SUMMARY OF THE INVENTION

In the light of the aforementioned problems encountered in prior art, the present invention hereby provides a novel semiconductor device and method of manufacturing the same, characterized by a lowered oxide-semiconductor layer and/or forming a protective insulating layer thereon in the device, thereby preventing the oxide-semiconductor layer from the impact of later etching or cleaning process.

One aspect of the present invention is to provide a semiconductor device, including a substrate, a first metal layer on the substrate, a first dielectric layer on the first metal layer, a dual damascene metal structure through the first metal layer and the first dielectric layer and partly in the substrate, an oxide-semiconductor layer between the dual damascene metal structure and the first metal layer, and a metal oxide layer on the oxide-semiconductor layer and between the dual damascene metal structure and the oxide-semiconductor layer, wherein the top surface of oxide-semiconductor layer is lower than the top surface of first dielectric layer, the metal oxide layer includes at least two metal elements and covers the top surface of oxide-semiconductor layer.

Another aspect of the present invention is to provide a method of manufacturing semiconductor device, including steps of providing a first metal layer and a first dielectric layer on the first metal layer, performing a patterning process to form a recess extending through the first dielectric layer and the first metal layer in vertical direction, forming an oxide-semiconductor layer on a surface of the recess, performing a removing process to remove parts of the oxide-semiconductor layer, so that a top surface of the oxide semiconductor layer is lower than a top surface of the first dielectric layer, forming metal a oxide layer on the oxide-semiconductor layer, and forming a dual damascene metal structure in the recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic cross-section illustrating a semiconductor device in accordance with one embodiment of present invention;

FIG. 2 is a schematic cross-section illustrating a semiconductor device in accordance with another embodiment of present invention;

FIG. 3 is a schematic cross-section illustrating a semiconductor device in accordance with still another embodiment of present invention;

FIGS. 4-8 are schematic cross-sections illustrating a process flow of a semiconductor device in accordance with one embodiment of present invention;

FIGS. 9-11 are schematic cross-sections illustrating a process flow of lowering the height of an oxide-semiconductor layer in accordance with one embodiment of present invention; and

FIGS. 12-19 are schematic cross-sections illustrating a process flow of a semiconductor device in accordance with another embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of present disclosure and various features in the embodiments that are not conflicted with each other can be combined and rearranged in various ways. Without departing from the spirit and scope of present disclosure, modifications, equivalents, or improvements to the present disclosure are understandable to those skilled in the art and are intended to be encompassed within the scope of the present disclosure.

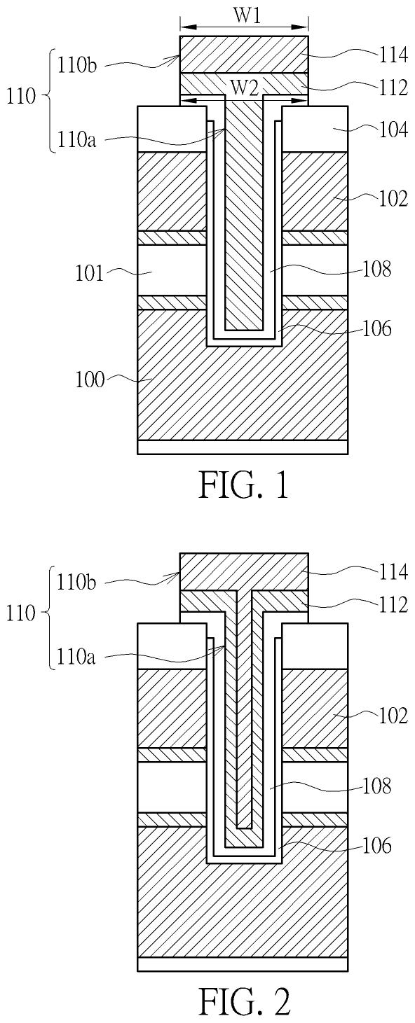

First, please refer to FIG. 1, which is a schematic cross-section of a semiconductor device in accordance with one embodiment of present invention. As shown in the figure, the semiconductor device of present invention includes a substrate 100. A second dielectric layer 101 is provided on the substrate 100, such as an inter-metal dielectric (IMD) layer, with material like silicon oxide. A first metal layer 102 is provided on the second dielectric layer 101, with material like tungsten (W) and may include barrier structure (ex. titanium nitride, TiN). Another first dielectric layer 104 is provided on the first metal layer 102.

Refer still to FIG. 1. The semiconductor device of present invention further includes a dual damascene metal structure 110. In the embodiment of present invention, the dual damascene metal structure 110 includes a lower part 110a and an upper part 110b, wherein the upper part 110b of dual damascene metal structure 110 is on a top surface of the first dielectric layer 104, such as a metal line, which may be a part of a third metal layer, while the lower part 110a extends vertically through the layer structure like first dielectric layer 104, first metal layer 102 and second dielectric layer 101 to the substrate 100 below, and parts of the lower part 110a is in the substrate 100, such as a via structure. Furthermore, the dual damascene metal structure 110 is comprised of a metal layer 114 and a barrier layer 112. In this embodiment, the metal layer 114 is on a top surface of the first dielectric layer 104 and is a part of upper part 110b, with material like tungsten (W). The barrier layer 112 also has a part on the top surface of first dielectric layer 104 between the metal layer 114 and first dielectric layer 104, which is a part of the upper part 110b and may prevent the metal component of metal layer 114 from diffusing into the dielectric layer below. Furthermore, as shown in FIG. 1, the barrier layer 112 is provided with a part extending into the layer structure, constituting the lower part 110a of entire dual damascene metal structure 110. The material of barrier layer 112 may be titanium nitride (TiN). In addition, please note that although the lower part 110a of dual damascene metal structure 110 in the embodiment extends through only one first metal layer 102, the lower part 110a of dual damascene metal structure 110 in other embodiment may extend through, but not limited to, multiple metal layers and dielectric layers.

Refer still to FIG. 1. With respect to the lower part 110a of dual damascene metal structure 110, an oxide-semiconductor layer 106 and a metal oxide layer 108 are provided between the lower part 110a and the layer structure, wherein the oxide-semiconductor layer 106 is conformally on the surface of via in the first dielectric layer 104, first metal layer 102, second dielectric layer 101 and substrate 100, with its top surface lower than the top surface of first dielectric layer 104. In the embodiment of present invention, the material of oxide-semiconductor layer 106 may be indium gallium zinc oxide (IGZO), which may be a channel layer of a vertical channel-all-around field effect transistor (CAA-FET) device. In another aspect, the metal oxide layer 108 is conformally on the oxide-semiconductor layer 106 and between the barrier layer 112 of dual damascene metal structure 110 and the oxide-semiconductor layer 106. More specifically, the metal oxide layer 108 is provided with a part on the top surface of first dielectric layer 104 between the barrier layer 112 and the first dielectric layer 104. The part of metal oxide layer 108 in the via covers the top surface of oxide-semiconductor layer 106 and is between the lower part 110a of dual damascene metal structure 110 and oxide-semiconductor layer 106. In the embodiment of present invention, the metal oxide layer 108 includes at least two metal elements, such as hafnium zirconium oxide (HfZrO₂), which may function as a gate oxide layer of a CAA-FET device, while the dual damascene metal structure 110 functions as a gate of the CAA-FET device, and the first metal layer 102 and substrate 100 function as source/drain of the CAA-FET device. In the aspect of dimension, the horizontal width W1 of upper part 110b of dual damascene metal structure 110 is larger than the horizontal width W2 of the top surface of first dielectric layer 104.

Please refer to FIG. 2, which is a schematic cross-section illustrating a semiconductor device in accordance with another embodiment of present invention. In other embodiment, as shown in FIG. 2, the metal layer 114 of dual damascene metal structure 110 is also provided with a part extending into the layer structure, constituting the lower part 110a of entire dual damascene metal structure 110 collectively with the barrier layer 112. In this embodiment, the barrier layer 112 of lower part 110a of dual damascene metal structure 110 is between the metal layer 114 and metal oxide layer 108, which may prevent the metal component of metal layer 114 from diffusing into the surrounding metal oxide layer 108 and oxide-semiconductor layer 106.

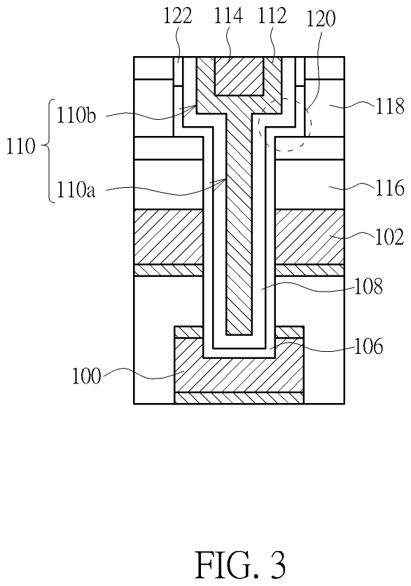

Please refer to FIG. 3, which is a schematic cross-section illustrating a semiconductor device in accordance with still another embodiment of present invention. The feature of this embodiment is that the lower part and upper part of the dual damascene metal structure are both formed in a dielectric layer, and the oxide-semiconductor layer and metal oxide layer are provided with ladder feature. As shown in FIG. 3, the semiconductor device in this embodiment includes a substrate 100. A first metal layer is provided on the substrate 100, with material like tungsten (W) and may also include barrier structure. Different from the aforementioned embodiment, a third dielectric layer 116 and a fourth dielectric layer 118 are provided sequentially on the first metal layer 102, such as an IMD layer. The third dielectric layer 116 and fourth dielectric layer 118 may be a multiplayer structure formed by silicon oxide layer and silicon nitride layer, which may facilitate later dual damascene process.

Refer still to FIG. 3. The semiconductor device of present invention further includes a dual damascene metal structure 110. In the embodiment of present invention, the dual damascene metal structure 110 includes a lower part 110a and an upper part 110b, wherein the upper part 110b of dual damascene metal structure 110 is in the fourth dielectric layer 118, such as a metal line, which may be a part of a third metal layer, while the lower part 110a extends vertically through the layer structure like third dielectric layer 116 and first metal layer 102 to the substrate 100 below and partly in the substrate 100, such as a via. Similarly, the dual damascene metal structure 110 is comprised of a metal layer 114 and a barrier layer 112. In this embodiment, the metal layer 114 is in fourth dielectric layer 118 and is a part of upper part 110b, with material like tungsten (W). The barrier layer 112 is also provided between metal layer 114 and fourth dielectric layer 118 and is a part of upper part 110b, which may prevent the metal component of metal layer 114 from diffusing into surrounding metal oxide layer 108. In addition, as shown in FIG. 3, the barrier layer 112 is further provided with a part extending into the layer structure, constituting the lower part 110a of entire dual damascene metal structure 110. The material of barrier layer 112 may be titanium nitride (TiN). In addition, please note that although the lower part 110a of dual damascene metal structure 110 in the embodiment extends through only one first metal layer 102, the lower part 110a of dual damascene metal structure 110 in other embodiment may extend through, but not limited to, multiple metal layers and dielectric layers.

Refer still to FIG. 3. The dual damascene metal structure 110 is further provided with an oxide-semiconductor layer 106 and a metal oxide layer 108, wherein the oxide-semiconductor layer 106 is conformally on the surface of via in the fourth dielectric layer 118, third dielectric layer 116, first metal layer 102 and substrate 100, with its top surface lower than the top surface of fourth dielectric layer 118. In the embodiment of present invention, the material of oxide-semiconductor layer 106 may be IGZO, which may be a channel layer of a CAA-FET device. In another aspect, the metal oxide layer 108 is conformally on the oxide-semiconductor layer 106 between the barrier layer 112 of dual damascene metal structure 110 and the oxide-semiconductor layer 106. The metal oxide layer 108 may include at least two metal elements, such as hafnium zirconium oxide (HfZrO_), which may function as a gate oxide layer of CAA-FET device, while the dual damascene metal structure 110 functions as a gate of the CAA-FET device, and the first metal layer 102 and substrate 100 function as source/drain of the CAA-FET device. In addition, in this embodiment, an insulating layer 122 is provided on the top surface of lower oxide-semiconductor layer 106, such as a silicon oxide layer, between the fourth dielectric layer 118 and metal oxide layer 108. In this embodiment, the top surfaces of upper part 110b of dual damascene metal structure 110, metal oxide layer 108, insulating layer 122 and fourth dielectric layer 118 are flush. Please note that in this embodiment, since the metal line structure of upper part 110b of dual damascene metal structure 110 is formed through dual damascene process in the fourth dielectric layer 118 rather than on the fourth dielectric layer 118, surrounding metal oxide layer 108 and oxide-semiconductor layer 106 will be provided with ladder features 120 that are conformal to entire dual damascene metal structure 110 near the connecting position of upper part 110b and lower part 110a of the dual damascene metal structure 110, which is one of the main feature different from the one of aforementioned embodiment.

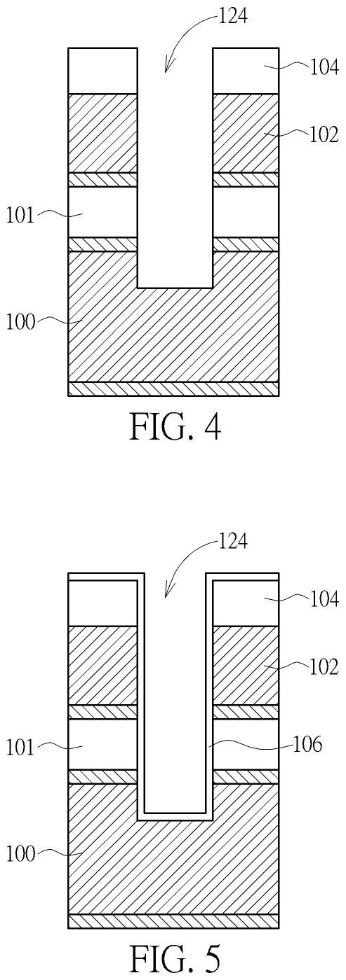

After describing various structural patterns of the semiconductor device in present invention, the process flow of the semiconductor device of present invention will be described hereinafter with reference sequentially to FIG. 4 through FIG. 8. These figures will clearly show relative positions and connections in vertical direction between the components involved in the process of present invention, wherein the semiconductor device formed in this process corresponds to the aforementioned semiconductor device shown in FIG. 1.

First, please refer to FIG. 4. In the beginning of the process, a substrate 100 is provided. The substrate 100 may be a silicon substrate with various semiconductor devices and back-end-of-line (BEOL) interconnects formed thereon. A second dielectric layer 101 (ex. IMD layer), a first metal layer 102 (ex. second metal layer M2) and another first dielectric layer 104 (ex. another IMD layer) are formed sequentially on the substrate 100. A patterning process is then performed to form a recess 124 in the aforementioned first dielectric layer 104, first metal layer 102, second dielectric layer 101 and substrate 100, such as a via structure. Please note that although the recess 124 in the embodiment extends through only one first metal layer 102, the recess 124 in other embodiment may extend through, but not limited to, multiple metal layers.

Please refer to FIG. 5. After the recess 124 is formed, an oxide-semiconductor layer 106 is then formed on the recess 124. The material of oxide-semiconductor layer 106 may be IGZO, which may be formed conformally on the surface of recess 124 and first dielectric layer 104 through atomic layer deposition (ALD) process, and may function as a channel layer of a CAA-FET device.

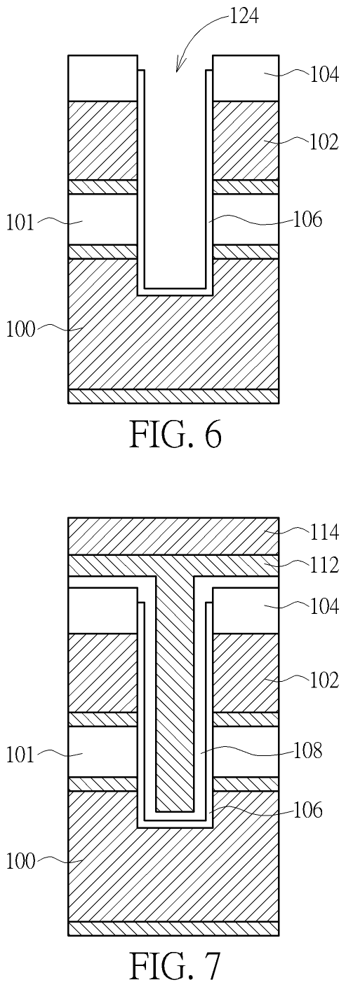

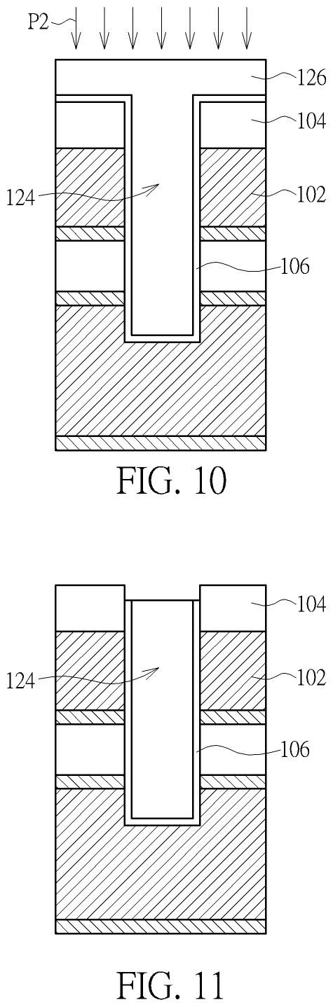

Please refer to FIG. 6. After the oxide-semiconductor layer 106 is formed, a removing process is then performed to remove parts of the oxide-semiconductor layer 106 above a predetermined height, so that the top surface of oxide-semiconductor layer 106 would be lower than the top surface of first dielectric layer 104, while the part of oxide-semiconductor layer 106 on the top surface of first dielectric layer 104 is completely removed. In the present invention, the removing process may include different methods. For example, as shown in FIG. 9, an ion bombardment process P1 at a tilt angle may be performed to ion bombard and remove the oxide-semiconductor layer 106. The angle of ion bombardment process may be adjusted in the embodiment to control the height of resulting oxide-semiconductor layer 106. Alternatively, as the approaches shown in FIG. 10 and FIG. 11, after the oxide-semiconductor layer 106 is formed, a photoresist 126 is first formed on the oxide-semiconductor layer 106. The photoresist 126 would fill into the recess 124 and cover the top surface of entire oxide-semiconductor layer 106. An etch back process P2 is then performed to remove the photoresist 126 and oxide-semiconductor layer 106 above a predetermined height. In this way, the photoresist 126 and oxide-semiconductor layer 106 on the top surface of first dielectric layer 104 will be removed completely, and the oxide-semiconductor layer 106 on the sidewall and bottom surface of recess 124 will not be removed due to the protection of photoresist 126, with its top surface lower than the top surface of surrounding first dielectric layer 104. The photoresist 126 may then be removed through ashing process.

Refer back to FIG. 7. After the height of oxide-semiconductor layer 106 is lowered, a metal oxide layer 108, a barrier layer 112 and a metal layer 114 are formed sequentially. As shown in FIG. 7, the metal oxide layer 108 may be formed conformally on the surface of oxide-semiconductor layer 106 and first dielectric layer 104 through ALD process, with its material may include at least two metal elements, such as hafnium zirconium oxide (HfZrO_), which may function as a gate oxide layer of a CAA-FET device. The barrier layer 112 may also be formed on the surface of metal oxide layer 108 through ALD process, wherein the barrier layer 112 fills up the space of remaining recess 124 and covers the surface of entire metal oxide layer 108. The material of barrier layer 112 may be titanium nitride (TiN). The metal layer 114 may be formed on the top surface of barrier layer 112 through chemical vapor deposition (CVD) process, with material like tungsten (W). It can be seen in the figure that, since the top surface of oxide-semiconductor layer 106 is lower than the top surface of first dielectric layer 104 in this embodiment, the metal oxide layer 108 formed later would completely cover the oxide-semiconductor layer 106 to provide protective effect.

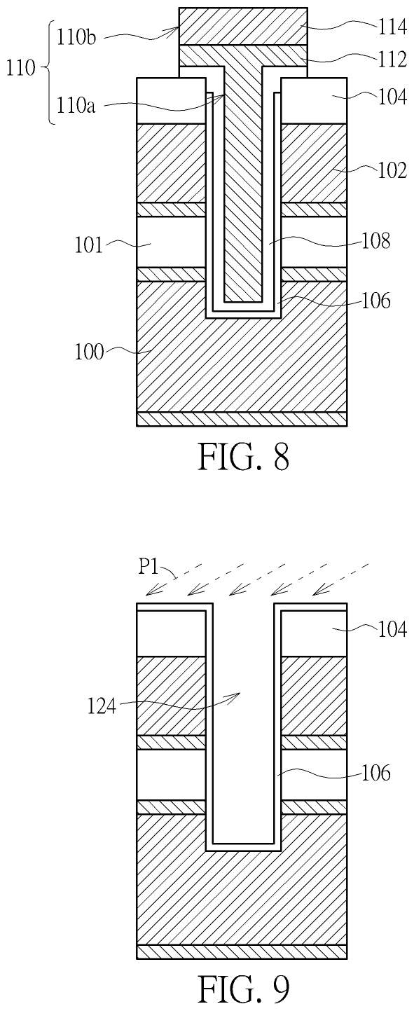

Please refer to FIG. 8. After the metal oxide layer 108, barrier layer 112 and metal layer 114 are formed, a patterning process is then performed to pattern the metal oxide layer 108, barrier layer 112 and metal layer 114 on the top surface of first dielectric layer 104, thereby forming the upper portion 110b of dual damascene metal structure 110, such as metal lines or metal pads, while the barrier layer 112 in the recess functions as a lower part 110a of dual damascene metal structure 110, such as via. Please note that in the present invention, since the oxide-semiconductor layer 106 is completely covered by the metal oxide layer 108, the oxide-semiconductor layer 106 is protected by the metal oxide layer 108 and will not be influenced by later patterning process or cleaning process, thereby solving the problem of oxide-semiconductor layer 106 damaged or contaminated by later process in prior art, which is the advantage of the structure and process of present invention.

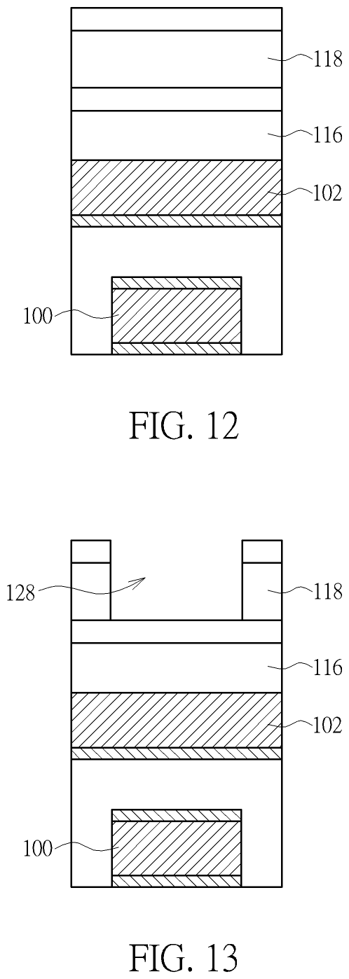

The process flow of the semiconductor device of present invention will be described hereinafter with reference sequentially to FIG. 12 through FIG. 19. These figures will clearly show relative positions and connections direction between the components involved in the process of present invention, wherein the semiconductor device formed in this process corresponds to the aforementioned semiconductor device shown in FIG. 3.

First, please refer to FIG. 12. In the beginning of the process, a substrate 100 is provided. The substrate 100 may be a silicon substrate with various semiconductor devices, IMD layers and BEOL interconnects (ex. first metal layer M1) formed thereon, and may include multilayer structure like metal layer (ex. tungsten (W)) and barrier layer (ex. titanium nitride (TiN)). A first metal layer 102 is formed on the substrate 100 with material like tungsten (W) and may also include barrier structure. Different from the aforementioned embodiment, a third dielectric layer 116 and a fourth dielectric layer 118 are provided sequentially on the first metal layer 102, such as an IMD layer. The third dielectric layer 116 and fourth dielectric layer 118 may be a multiplayer structure formed by silicon oxide layer and silicon nitride layer, which may facilitate later dual damascene process.

Please refer to FIG. 13. After the substrate 100 is provided, a patterning process is then performed to form a recess 128 in the topmost fourth dielectric layer 118. This patterning process may use the upper silicon nitride layer in the third dielectric layer 116 as an etch stop layer. The resulting recess 128 defines the shape of upper part 110b of dual damascene metal structure 110 to be formed later, such as metal lines or metal pads.

Please refer to FIG. 14. After the recess 128 is formed, another patterning process is then performed to form another recess 130 in the third dielectric layer 116, first metal layer 102 and substrate 100. The recess 130 would extend through the layer structure like third dielectric layer 116 and first metal layer 102 to the substrate 100 and partly in the substrate 100. The resulting recess 130 defines the shape of lower part 110a of dual damascene metal structure 110 to be formed later, such as a via, with its horizontal width smaller than the one of recess 128 above and completely overlaps the recess 128 in vertical direction, thereby forming a dual damascene recess. Please note that although the recess 130 in the embodiment extends through only one third dielectric layer 116 and one first metal layer 102, the recess 130 in other embodiment may extend through, but not limited to, multiple dielectric layers and metal layers.

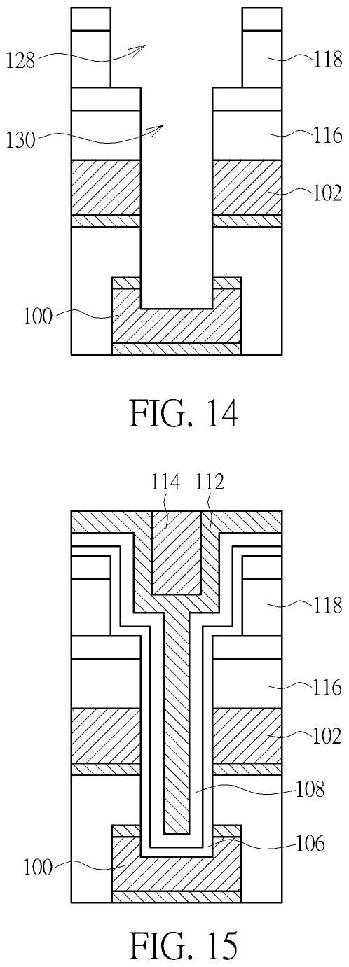

Please refer to FIG. 15. After the dual damascene metal recess 128/130 is formed, an oxide-semiconductor layer 106, a metal oxide layer 108, a barrier layer 112 and a metal layer 114 are formed sequentially. As shown in the figure, the oxide-semiconductor layer 106 may be formed conformally on the surface of dual damascene metal recess and fourth dielectric layer 118 through ALD process with material like IGZO, which may function as a channel layer of a CAA-FET device. The metal oxide layer 108 may be formed conformally on the surface of oxide-semiconductor layer 106 through ALD process, with its material may include at least two metal elements, such as HfZrO₂, which may function as a gate oxide layer of the CAA-FET device. The barrier layer 112 may also be formed on the surface of metal oxide layer 108 through ALD process to fill up remaining recess space. The material of barrier layer 112 may be titanium nitride (TiN). The metal layer 114 may fill up the recess formed on the barrier layer 112 through CVD process, with material like tungsten (W).

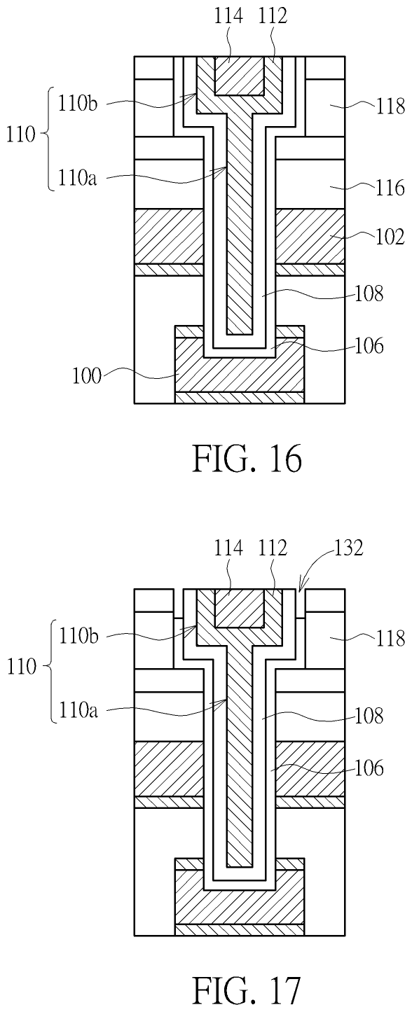

Please refer to FIG. 16. After the layer structures like oxide-semiconductor layer 106, metal oxide layer 108, barrier layer 112 and metal layer 114 are formed, a planarization process, ex. chemical mechanical planarization (CMP) process, is then performed to remove those layer structures on the top surface of fourth dielectric layer 118. The planarization process may use the upper silicon nitride layer of fourth dielectric layer 118 as a grinding stop layer. After planarization, the top surfaces of oxide-semiconductor layer 106, metal oxide layer 108, barrier layer 112 and metal layer 114 are flush with the surrounding fourth dielectric layer 118 and are all exposed from the surface, thereby forming a dual damascene metal structure 110 in the dual damascene recess, including the metal line of an upper part 110b and the via of an lower part 110a, and the lower part 110a of dual damascene metal structure 110 is connected with the substrate 100.

Please refer to FIG. 17. After the dual damascene metal structure 110 is formed, a selective etching process directed to the oxide-semiconductor layer 106 is then performed, such as a wet etching process using diluted hydrofluoric acid (DHF) as etchant, to etch parts of the oxide-semiconductor layer 106, thereby forming a recess 132 on the oxide-semiconductor layer 106 between metal oxide layer 108 and surrounding fourth dielectric layer 118.

Please refer to FIG. 18. After the recess 132 is formed, an ALD process is then performed to form an insulating layer 122, such as a silicon oxide layer. As shown in FIG. 18, the insulating layer 122 is formed on the surface of fourth dielectric layer 118, metal oxide layer 108, barrier layer 112 and metal layer 114 and fills up the aforementioned recess 132 formed by etching the oxide-semiconductor layer 106.

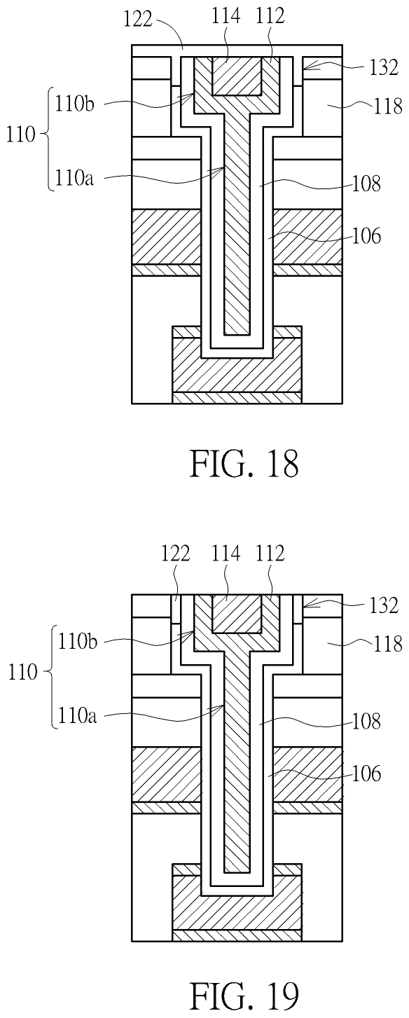

Please refer to FIG. 19. After the insulating layer 122 is formed, an etch back process is then performed to remove the insulating layer 122 outside the recess 132, thereby exposing the upper part 110b of dual damascene metal structure 110, and the remaining insulating layer 122 fills in the recess 132 to protect the oxide-semiconductor layer 106 below from the damage or contamination caused by later etching or cleaning process, which is the advantage of the structure and process of present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first metal layer on said substrate;
a first dielectric layer on said first metal layer;
a dual damascene metal structure extending through said first metal layer and said first dielectric layer and partly in said substrate;
an oxide-semiconductor layer between said dual damascene metal structure and said first metal layer; and
a metal oxide layer on said oxide-semiconductor layer and between said dual damascene metal structure and said oxide-semiconductor layer;
wherein a top surface of said oxide-semiconductor layer is lower than a top surface of said first dielectric layer, said metal oxide layer comprises at least two metal elements and covers said top surface of said oxide-semiconductor layer.

2. The semiconductor device of claim 1, wherein said metal oxide layer completely covers said oxide-semiconductor layer and partly on said top surface of said first dielectric layer.

3. The semiconductor device of claim 2, wherein said dual damascene metal structure comprises a lower part between said oxide-semiconductor layer and an upper part covering a top surface of said metal oxide layer.

4. The semiconductor device of claim 3, wherein said upper part of said dual damascene metal structure has a first maximum width, said metal oxide layer on said top surface of said first dielectric layer has a second maximum width, and said first maximum width is larger than said second maximum width.

5. The semiconductor device of claim 1, said oxide-semiconductor layer is provided with ladder feature.

6. The semiconductor device of claim 1, further comprising an insulating layer on a top surface of said oxide-semiconductor layer and between said first dielectric layer and said metal oxide layer.

7. The semiconductor device of claim 1, wherein said dual damascene metal structure comprises a barrier layer and a metal layer on said barrier layer.

8. The semiconductor device of claim 1, further comprising a second dielectric layer between said substrate and said first metal layer.

9. A method of manufacturing semiconductor device, comprising:
providing a first metal layer and a first dielectric layer on said first metal layer;
performing a patterning process to form a recess extending through said first dielectric layer and said first metal layer in vertical direction;
forming an oxide-semiconductor layer on a surface of said recess;
performing a removing process to remove parts of said oxide-semiconductor layer, so that a top surface of said oxide-semiconductor layer is lower than a top surface of said first dielectric layer;
forming a metal oxide layer on said oxide-semiconductor layer; and
forming a dual damascene metal structure in said recess.

10. The method of manufacturing semiconductor device of claim 9, wherein said removing process comprises performing an ion bombardment process at a tilt angle to remove parts of said oxide-semiconductor layer, so that said top surface of said oxide semiconductor layer is lower than said top surface of said first dielectric layer.

11. The method of manufacturing semiconductor device of claim 9, wherein said removing process comprises:
after said oxide-semiconductor layer is formed, forming a photoresist on said oxide-semiconductor layer;
performing an etch back process to remove parts of said oxide-semiconductor layer and said photoresist, so that said top surface of said oxide-semiconductor layer and a top surface of said photoresist are lower than said top surface of said first dielectric layer; and
removing said photoresist.

12. The method of manufacturing semiconductor device of claim 9, wherein said recess is a dual damascene recess, and said removing process comprises:
after said oxide-semiconductor layer, said metal oxide layer and said dual damascene metal structure are formed, performing a wet etching process to remove parts of exposed said oxide-semiconductor layer, thereby forming a recess between said first dielectric layer and said metal oxide layer;
forming an insulating layer in said recess and on said top surface of said oxide-semiconductor layer; and
performing an etch back process to remove said insulating layer on said top surface of said oxide-semiconductor layer, thereby exposing said dual damascene metal structure and remaining only said insulating layer in said recess.

13. The method of manufacturing semiconductor device of claim 9, wherein said metal oxide layer completely cover said oxide-semiconductor layer and partly on said top surface of said first dielectric layer.

14. The method of manufacturing semiconductor device of claim 13, wherein a lower part of said dual damascene metal structure is in said recess, and an upper part of said dual damascene metal structure is on said metal oxide layer outside said recess.

15. The method of manufacturing semiconductor device of claim 9, wherein said dual damascene metal structure comprises a barrier layer and a metal layer on said barrier layer.

16. The method of manufacturing semiconductor device of claim 15, wherein said metal layer and said barrier layer are both in said recess.
